(19) United States
(12) Patent Application Publication
(10) Pub. No.: US 2026/0010272 A1
(43) Pub. Date: Jan. 8, 2026

(54) INTERACTIVE GAME DESIGN SYSTEM

(71) Applicant: DISNEY ENTERPRISES, INC., Burbank, CA (US)

(72) Inventors: Thomas F. Johnson, Winter Garden, FL (US); Blake A. Fricker, Oxford, FL (US); Evan L. Klein, Winter Garden, FL (US); Eric Scott Policaro, Mars, PA (US); Roberto Emmanuelle Santana Centeno, Orlando, FL (US); Steven C. Eaton, Winter Garden, FL (US); Thomas Carey Arthur, Orlando, FL (US); Dennis Loren Miller, III, Orlando, FL (US); Jeffrey L. Elbert, Los Angeles, CA (US); John Kepler Lewis, Clermont, FL (US); Scott Depriest, Orlando, FL (US); Jose Lugos Corpuz, Ocoee, FL (US)

(21) Appl. No.: 18/764,631

(22) Filed: Jul. 5, 2024

(51) Int. Cl. G06F 3/04815; G06F 30/20

(52) U.S. Cl. CPC G06F 3/04815; G06F 30/20

(57) ABSTRACT

A system for simulating an interactive physical environment includes: a physical actuator positioned within the interactive physical environment; and a translator configured to: generate a digital representation of the interactive physical environment including a virtual actuator in a digital location, where the virtual actuator is representative of the physical actuator; generate a virtual command for an action of the virtual actuator; translate the virtual command into a physical signal for the physical actuator; and output the physical signal to the physical actuator.

### BACKGROUND

Interactive environments such as amusement park experiences, mazes, and other such immersive experiences can offer guests a rich experience by weaving together portions of storytelling with either physical or virtual interactions that reinforce the story. In such experiences, guests may be placed within an environment in which they make decisions or take actions that influence and change the narrative, often in a branching manner. For example, if a guest decides to open a physical door, the narrative may adapt to provide experiences to the guest based on whether or not they opened the door, e.g., getting access to a character, display, points, or other element that is due to the door being opened.

Such branching can create a high number of possible permutations for guest experiences, in some cases, millions of different possible combinations, depending on the complexity of the immersive environment. This can make it difficult to design, plan, execute, operate, and/or troubleshoot immersive narrative experiences. The problem is compounded by including different electrical, software, and physical systems.

### BRIEF SUMMARY

In one embodiment, a system for simulating an interactive physical environment includes: a physical actuator positioned within the interactive physical environment; and a translator configured to: generate a digital representation of the interactive physical environment including a virtual actuator in a digital location, wherein the virtual actuator is representative of the physical actuator; generate a virtual command for an action of the virtual actuator; translate the virtual command into a physical signal for the physical actuator; and output the physical signal to the physical actuator.

Optionally, in some embodiments, the translator is further configured to receive a guest interaction input interacting with at least one of the virtual actuator or the physical actuator; and activate the at least one of the virtual actuator or the physical actuator based on the guest interaction input.

Optionally, in some embodiments, the guest interaction input includes a guest interaction within the interactive physical environment or a simulated guest interaction within the digital representation.

Optionally, in some embodiments, the translator includes a software layer; a communications layer in communication with the software layer; and a hardware layer in communication with the software layer, the communications layer, or both.

Optionally, in some embodiments, simulating the virtual actuator includes executing by the software layer a simulation that emulates a characteristic of the physical actuator.

Optionally, in some embodiments, simulating the virtual actuator includes causing the processing element to execute the communications layer to emulate a data exchange with the physical actuator.

Optionally, in some embodiments, simulating the virtual actuator includes causing the processing element to execute the hardware layer to create a physical output compatible with the physical actuator.

Optionally, in some embodiments, translator includes at least one of a proximity translator, a show cueing translator, a visual analytics translator, or a messaging translator.

Optionally, in some embodiments, simulating the guest interaction includes simulating a guest device or a guest archetype.

Optionally, in some embodiments, simulating the guest interaction includes autonomously simulating a plurality of guests interacting with the interactive environment.

Optionally, in some embodiments, the processing element is configured to: display a graphical user interface including a two-dimensional representation of the interactive environment; receive, via the graphical user interface, a user input related to the interactive environment, translate the user input into the physical signal, transmit the physical signal to the physical actuator; in response to the transmission of the physical signal, receive a confirmation signal from the physical actuator, and update the graphical user interface based on the confirmation.

Optionally, in some embodiments, the system further includes a digital twin of the interactive environment.

In one embodiment, a method of simulating an interactive physical environment includes positioning a physical actuator within the interactive physical environment; generating, via a processing element, a digital representation of the interactive physical environment including a virtual actuator in a digital location, wherein the virtual actuator is representative of the physical actuator; generating, via the processing element, a virtual command for an action of the virtual actuator; translating, via the processing element, the virtual command into a physical signal for the physical actuator; and outputting, via the processing element, the physical signal to the physical actuator.

Optionally, in some embodiments, the method further includes executing, via the processing element, a translator including: a software layer; a communications layer in communication with the software layer; and a hardware layer in communication with the software layer, the communications layer or both, wherein the translator is configured to simulate the virtual actuator.

Optionally, in some embodiments, simulating the virtual actuator includes causing the processing element to perform at least one of: executing the software layer to emulate a characteristic of the physical actuator; executing the communications layer to emulate a data exchange with the physical actuator; or executing the hardware layer to create a physical output compatible with the physical actuator.

Optionally, in some embodiments, simulating the guest interaction includes simulating a guest device or a guest archetype.

Optionally, in some embodiments, the processing element is configured to: display a graphical user interface including a two-dimensional representation of the interactive environment; receive, via the graphical user interface, a user input related to the interactive environment, translate the user input into the physical signal, transmit the physical signal to the physical actuator; in response to the transmission of the physical signal, receive a confirmation signal from the physical actuator, and update the graphical user interface based on the confirmation.

Ion one embodiment, a method for simulating guest interactions within a physical interactive environment includes: generating a digital twin of the physical interactive environment, the digital twin including a plurality of virtual actuators corresponding to physical actuators positioned within the physical interactive environment, wherein the plurality of virtual actuators are configured to vary environmental characteristics based on a guest input and creative constraints; providing a plurality of guest inputs to the plurality of virtual actuators, wherein the plurality of guest inputs are different from one another; and outputting data corresponding to the varied environmental characteristics and creative constraints based on the provided plurality of guest inputs.

Optionally, in some embodiments, the plurality of guest inputs is randomly generated.

Optionally, in some embodiments, the plurality of guest inputs is based on historical guest inputs from guests interacting with the physical interactive environment.

### BRIEF DESCRIPTION OF THE DRAWINGS

FIG. 1 illustrates an embodiment of an interactive environment.

FIG. 2 is a schematic showing an embodiment of an interactive environment design system suitable for use with the interactive environment of FIG. 1.

FIG. 3A is a schematic of an embodiment of a translator for use with the interactive environment design system of FIG. 2.

FIG. 3B is a detailed schematic of the interactive environment design system of FIG. 2 suitable for use with the interactive environment of FIG. 1.

FIG. 4A is a schematic of a portion of the interactive environment of FIG. 1 in a first configuration.

FIG. 4B is a schematic of a portion of the interactive environment of FIG. 1 in a second configuration.

FIG. 4C is a schematic of a portion of the interactive environment of FIG. 1 in a third configuration.

FIG. 5 is a flow chart of a method of simulating an interactive environment using the interactive environment design system of FIG. 2.

FIG. 6 is a simplified block diagram of components of a computing system of the interactive environment of FIG. 1 or interactive environment design system of FIG. 2.

### DETAILED DESCRIPTION

Interactive environments may be forms of interactive storytelling that engage the audience, blurring the lines between fiction and reality. Such entertainment experiences may involve the use of technologies such as sensory effects like visual effects (e.g., lighting, display of visual media, etc.), auditory, olfactory, haptic effects, virtual reality (“VR”) (broadly including virtual reality, augmented reality (“AR”), and/or mixed reality (“MR”)) to create a deeply immersive and interactive experience for the guest. This type of entertainment often places the guest at the center of a narrative, allowing them to make choices and influence the outcome of the story, resulting in a deeply engaging and captivating experience. For example, an interactive environment may include an interactive physical space that includes physical, digital, virtual, and/or sensory effect (e.g., lighting, motion, smell, sound, wind, etc.) outputs.

To create such interactive environments, technologists (e.g., engineers, mechanics, effects artists, computer programmers, etc.) weave together many different physical and virtual technologies to serve and realize the creative vision of one or more designers (e.g., story tellers, writers, visual artists, sound artists, directors, etc.).

An interactive environment typically includes physical features or aspects to enable a “real life” interaction for the guests. For example, a building, walls, doors, displays, lights, sounds, motion effects, smell effects, etc., can be set to enable a guest to physically experience some aspects of the environment and to help increase the realness of the immersive and interactive experience. Interactive environments also often use disparate, distributed software sub-systems, often with non-trivial or novel integrations, which use access to physical sensors for gathering data input. Integrating these sub-systems can be difficult and generally extends the time to deliver a project while in the field. The use of physical sensors presents an additional barrier to setting up a development environment; hardware and/or proper network configurations may not be readily available, leading to extended time in the field during the installation of software components when the hardware is available for testing. In addition, physical systems may be controlled by one or more controllers, such as local show controllers that activate, deactivate, and time effects in the physical environment in which the guests experience the interactive environment. These controllers in turn may be controlled by a master show controller of computing device that orchestrates the interactive environment for many guests on one, or possibly many, locations.

Conventionally, written documents and illustrations were created describing how an interactive environment should behave and be experienced by guests. These documents would then be converted to actual technical diagrams (e.g., with mechanical and software controls devices) to realize the environment. Such manual efforts are difficult and time consuming and often require a number of iterations.

Further, during the actual interactive experience, given the sheer number of choices that an individual guest could potentially make and the complexity for designing and testing such systems increases vastly. For example, a guest may make a choice to open (or not open) a door, which leads to one or more choices dependent on the first choice, and so on. The choices may be fully or partially overlapping and/or mutually exclusive. In some examples, a single guest could possibly have thousands or millions of unique experiences via their unique selections through the environment.

Disclosed systems provide an interactive environment design system that enable rapid deployment as well as development and testing of software components, physical hardware, virtual reality, effects, creative vision, narrative, and/or facility to enable partial or full integration during the project delivery lifecycle. Disclosed systems accurately simulate the physical and virtual aspects of an interactive environment at a level that can be used to improve or modify the creative aspects of the system, often without requiring such designers to have any specialized coding or training.

In one embodiment, an interactive environment design system is a multi-modal, platform that can help a designer prototype, develop, control, troubleshoot, and test distributed interactive experiences having multiple sub-systems (e.g., physical, virtual, etc.). An interactive environment design system enables pre-visualization, planning, and pre-integration of disparate interactive experiences. In some embodiments, after deployment, the system can be used to provide real-time management, monitoring, troubleshooting, and customization of the experience.

In some embodiments, the interactive environment design system provides a digital twin of an interactive environment. For example, the interactive environment design system can run simulations for both digital and real/physical actuators and experiences that can be used to help design and improve interactive experiences. The simulator can be used to output real control signals to actuate the physical actuators. The interactive environment design system can use an event stream, such as simulated guest interactions, to visualize the proposed design. As the interactive environment design matures, the simulation model can be translated into the physical environment. For example, simulated actuators can be replaced with real actuators, simulated sensors replaced with reals sensors, etc.

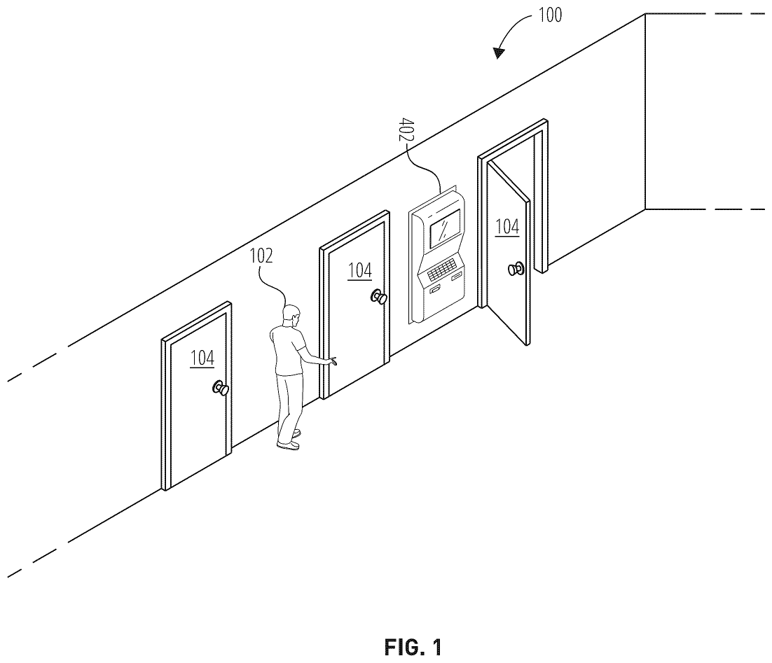

Turning to the figures, FIG. 1 shows an example of a guest 102 interacting with an interactive environment 100 including multiple physical engagement elements. In this example, the physical engagement elements include several doors 104 that the guest 102 may be able to open, depending on guest characteristics (e.g., prior actions, character role play or the like) and/or status of play within the interactive environment 100.

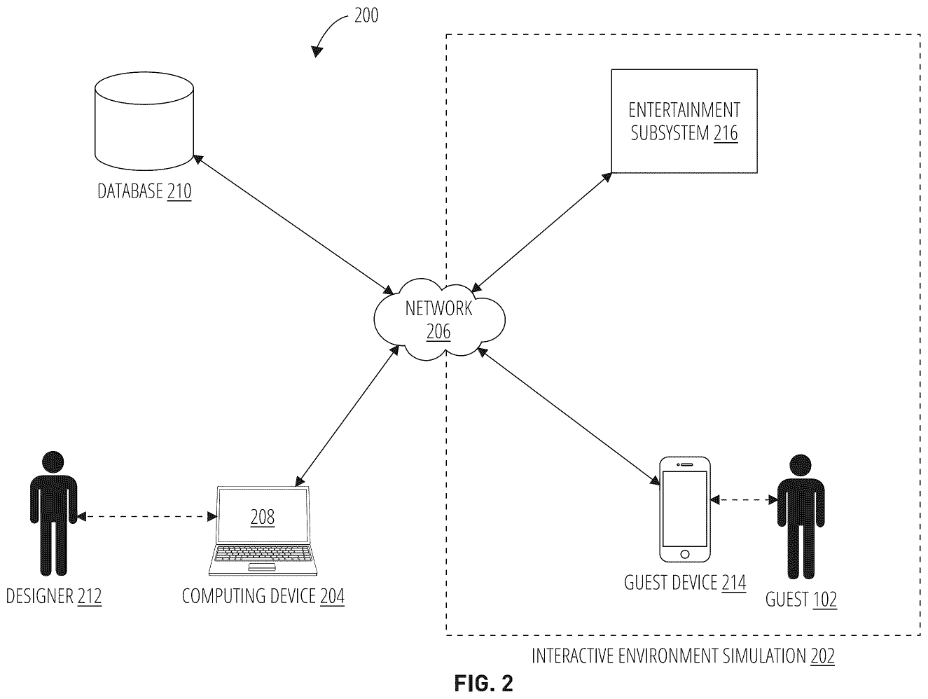

FIG. 2 shows a schematic of an embodiment of an interactive environment design system 200 suitable for use with an interactive environment 100. The system 200 may include a computing device 204, an entertainment subsystem 216, and/or a database 210, two or more of which may be in communication via a network 206. In some examples, the system 200 may be used to design or simulate the interactive environment 100 at a variety of levels of software, communication, and physical detail. In some examples, the system 200 may be used to manage, change, or otherwise operate the interactive environment 100. For example, once the interactive environment 100 is built, the system 200 may transform from being a design tool to being a management and operations tool that executes the interactive environment 100.

The computing device 204 may be any suitable device that receives data, performs calculations, and produces results based on those calculations. For example, the computing device 204 may be a server, a desktop computing system, a mainframe, a mesh of computing systems, a laptop or notebook computing system, a tablet computing system, a phone, a watch, an embedded computer system, a system-on-chip, a single-board computing system, or a combination of two or more of these.

The network 206 may be implemented using one or more of various systems and protocols for communications between computing devices. In various embodiments, the network 206 or various portions of the network 206 may be implemented using the Internet, a local area network (“LAN”), a wide area network (“WAN”), and/or other networks. In addition to traditional data networking protocols, in some embodiments, data may be communicated according to protocols and/or standards including near field communication (“NFC”), Bluetooth, cellular connections, Wi-Fi, Zigbee, and the like.

The database 210 may be any suitable type of database, such as a relational database management system (e.g., MySQL and Oracle), a so-called “NoSQL database” (e.g., MongoDB and/or Cassandra, an in-memory database (e.g., Redis), a data warehouses, a time-series database (e.g., InfluxDB) with support for the analysis of sensor and operational metrics over time, a graph database (e.g., Neo4j) that efficiently maps complex relationships, enhancing recommendations, and network analysis, etc. Time series and/or graph databases may be advantageously used in an interactive environment 100 or system 200 to simulate a guest 102 experience over time. In-memory databases of any time may be used, e.g., to provide real-time or near real-time access to data. The database 210 may hold data related to the configuration of the interactive environment 100, executable code that implements the system 200, individual guest 102 experiences, machine states, access logs, etc.

The system 200 is adapted to execute a simulation of an interactive environment 100. A guest device 214 may be any device that can communicate with the interactive environment 100 or system 200 and include optional sensors, For example, the guest device 214 may be a wearable device (e.g., a wrist band), key fob, smart phone, tablet, a toy (e.g., a magic wand or doll), earphones, virtual or augmented reality headset, or the like. An interactive environment 100 may communicate with a guest device 214, such a directly (e.g., nearfield communication, Bluetooth, Wi-Fi, or the like) or indirectly such as via the network 206 or another network.

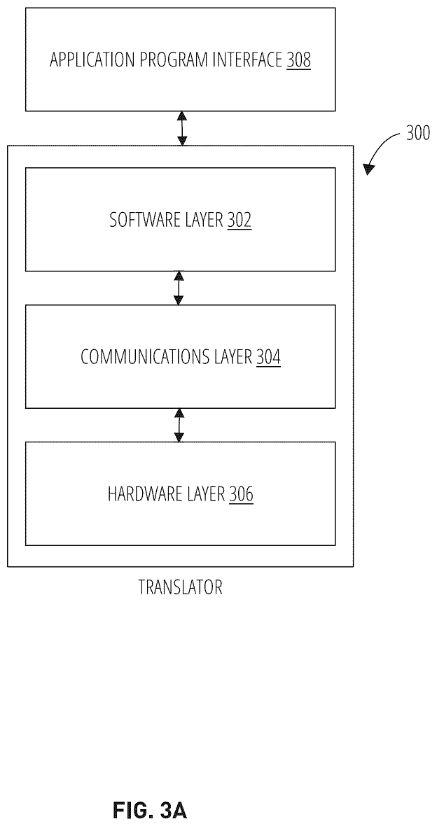

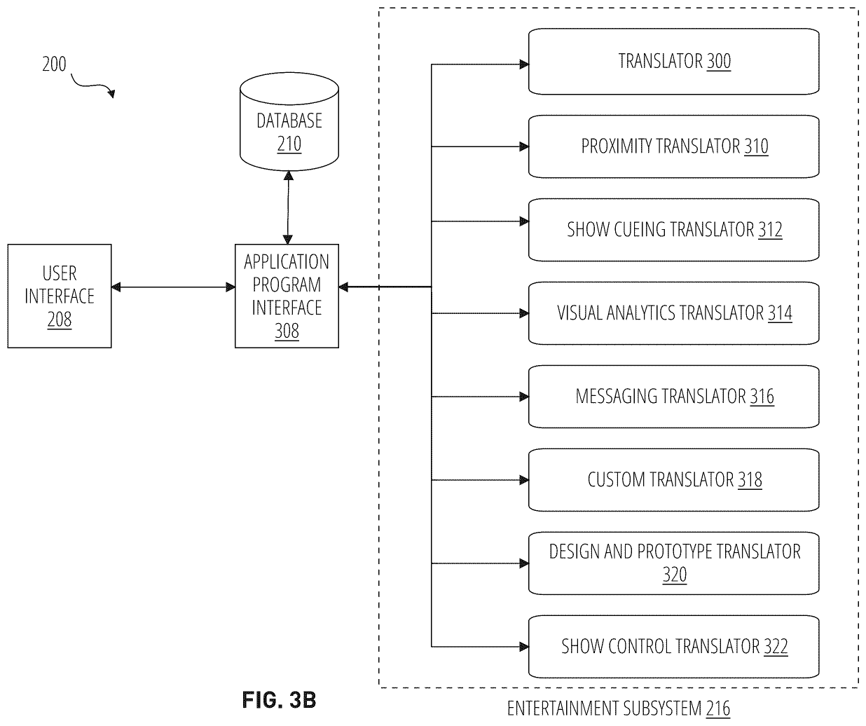

FIG. 3A shows an example of a translator 300. The translators receive data and/or inputs from the system 200, typically from an application program interface (“API”) 308 and effectuate or simulate physical actions in the interactive environment 100 or the simulation environment 202. A translator 300 typically processes actions related to a certain domain of the interactive environment 100. For example, one translator may process or simulate lighting effects, while another translator 300 processes or simulates proximity actions and data related to the presence of a guest 102. A translator 300 can include software and/or hardware that translates activities (e.g., signals, actuation or movement, etc.) between a simulation environment 202 and an actual interactive environment 100. For example, the translator 300 may receive a command from the system 200 and simulate a corresponding action based on the command in the simulation environment 202. For example, the system 200 may create digital or simulated actions by issuing commands to digital or simulated actuators (e.g., a command to simulate opening a door). Another example, the translator 300 may receive a command from the system 200 and cause that action to take place in the physical environment 100. For example, the system 200 can create physical outputs in the real world by creating commands that can be distributed to the physical actuators (e.g., a command to open a door). Similarly, the translator 300 may receive real or simulated inputs from real or simulated actuators or sensors in the actual interactive environment 100 or simulation environment 202.

As shown for example in FIG. 3A, a translator typically includes a software layer 302, a communications layer 304 and/or a hardware layer 306. One or more of the software layer 302, the communications layer 304, or the hardware layer 306 may be optional. The software layer 302 receives data and/or command from the application program interface 308 and may perform computations, transformations, or routing thereof. A processor may execute the software layer 302 to simulate a virtual actuator by emulating one or more characteristics of the physical actuator. For example, the software layer 302 may emulate an opening or closing speed of a door actuator. In some embodiments, the software layer 203 may include a physics-based model of an actuator that can emulate characteristics such as speed, weight, mass, inertia, torque, force, etc. The software layer 302 typically passes information to the communications layer 304.

In some embodiments, the communications layer 304 is an interface between the software layer 302 and the hardware layer 306. In some embodiments, the software layer 302 may pass information directly to, or receive information from, the hardware layer 306. The hardware layer 306 receives information from the software layer 302, the communications layer 304, or optionally directly from the application program interface 308. A processor may execute the communications layer 304 to simulate a virtual actuator by emulating a data exchange with the physical actuator. For example, where an actuator communicates with the network via a transmission control protocol/internet protocol (“TCP/IP”), the processor may generate TCP/IP packets transmitted from the software layer 302 to the communications layer 304 and vice versa to emulate communications with a real actuator.

In some examples, the hardware layer 306 effectuates some physical action in the interactive environment 100, based on the information it receives. In some examples, the hardware layer 306 simulates a physical action in the simulation environment 202. A processor may execute the hardware layer 306 to create a physical output compatible with the physical actuator. For example, a processor may cause the hardware layer 306 to generate a control signal (e.g., a 4-20 mA, 0-10V, etc.) compatible with a particular physical actuator being simulated. Any of the software layer 302, the communications layer 304, or the hardware layer 306 may transmit data (such as a confirmation or status signal) back to the application program interface 308 either directly or through the others of the software layer 302, communications layer 304, and/or hardware layer 306. In some embodiments, the translator 300 represents a hardware-in-the-loop simulation. The user interface 208 may be updated based on the confirmation signal. For example, the real hardware can be interfaced with the hardware layer 306 to increase the fidelity of the simulation environment 202, or to control the actual interactive environment 100.

Advantages of the translator 300 include the ability to simulate the interactive environment 100 at any desired level of software, communication, or hardware detail by creating so called “stubs” of the physical components of the interactive environment 100. Take the example of a door 104 in the interactive environment 100. As the interactive environment 100 is being developed the design may be set to include a door as part of the narrative. However, at this early stage, specific details about the door may not have yet been determined, e.g., hinged connection vs. slider, weight, structure and design, material, opening and closing forces, and the like. By using a door translator 300, the software layer 302 can be used (e.g., by the designer) to simulate the communications layer 304 and/or hardware layer 306 in a stub to experiment with different door types, properties, and technologies without having the expense and delay of building and installing different physical door options. As the design of the interactive environment 100 progresses towards a final design, the door actuator hardware is likely determined, but the physical door is not yet installed within the physical environment. In this case, the actual physical actuator can be connected to the hardware layer 306 and actuated as though the real door were in place.

Further, when the interactive environment 100 is being built, the translator 300 is able to troubleshoot and commission the door 104 and its actuator and vary the operation to achieve a desired result. Thus, the system 200 enables rapid, efficient development of interactive environments 100. The system 200 may also be used at the operation phase of the interactive environment 100 to manage, change, and/or control the interactive environment 100. For example, the system 200 may represent a virtual twin of the interactive environment 100.

FIG. 3B shows a schematic of an embodiment of the system 200 for use with an interactive environment 100, including specific examples of different translators. As shown for example in FIG. 3B, the system 200 may organize the translators into an entertainment subsystem 216 that simulates or effectuates one or more portions of the interactive environment 100. For example, the entertainment subsystem 216 may include a general translator 300 as described with respect to FIG. 3A, a proximity translator 310, a show cueing translator 312, a visual analytics translator 314, a messaging translator 316, one or more custom translators 318, a design and prototype translator 320, and/or a show control translator 322. The translators may communicate with the system 200 via an application program interface 308. The application program interface 308 translate data, commands, configurations, or the like between the translators and the database 210 and/or a user interface 208 of the computing device 204. In some embodiments, the application program interface 308 may include one or more of a hypertext transfer protocol interface, websocket interface, and/or a web interface. In some embodiments, the user interface 208 is displayed as part of a web application, standalone application, tablet application, phone application, or the like.

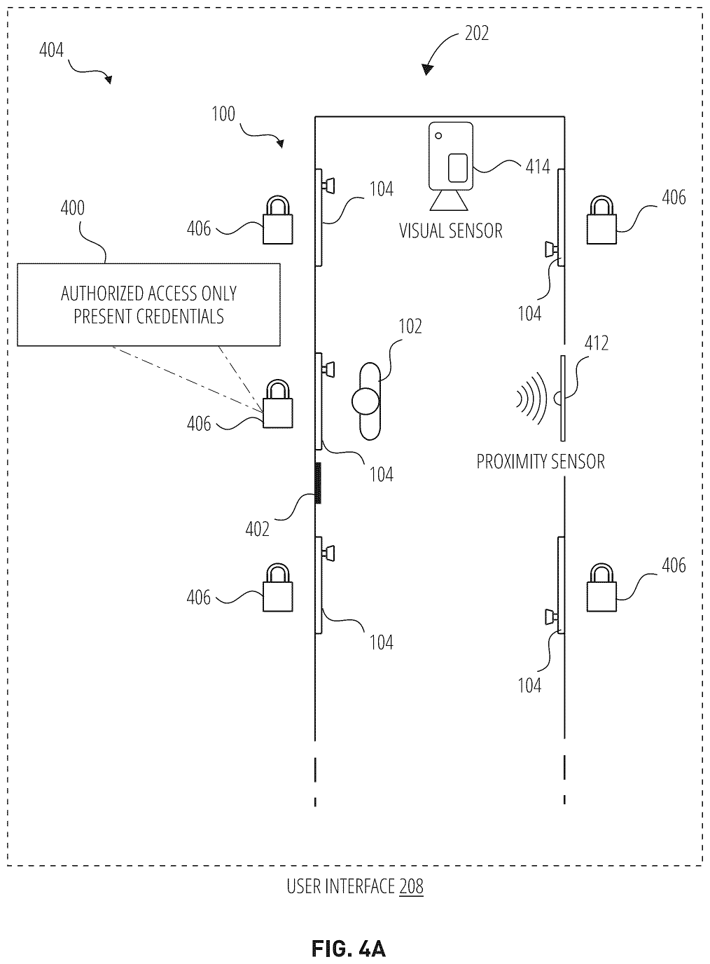

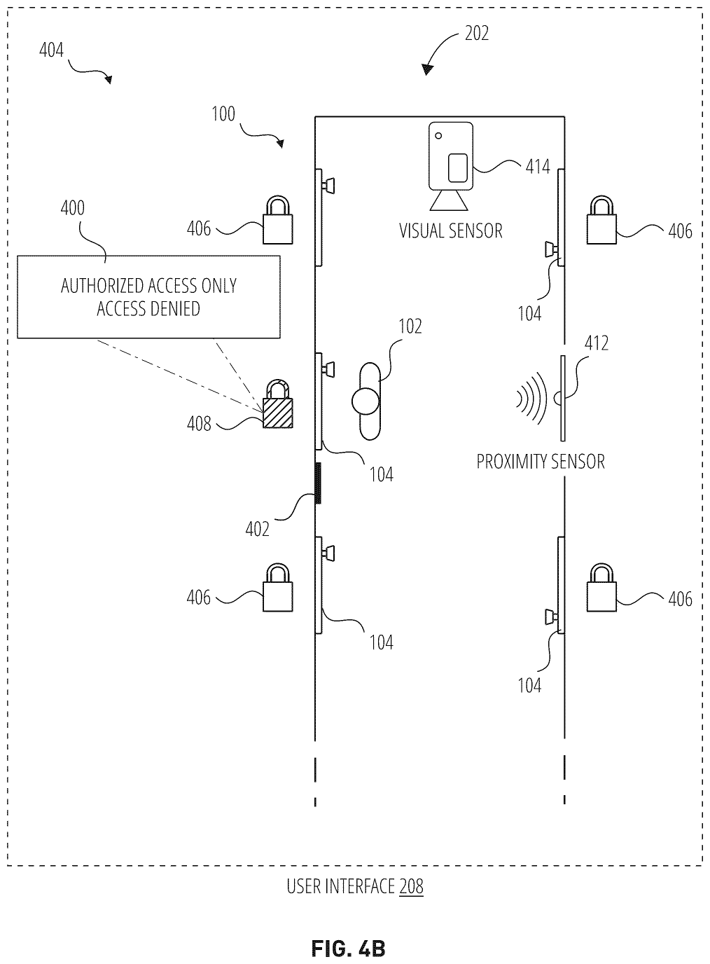

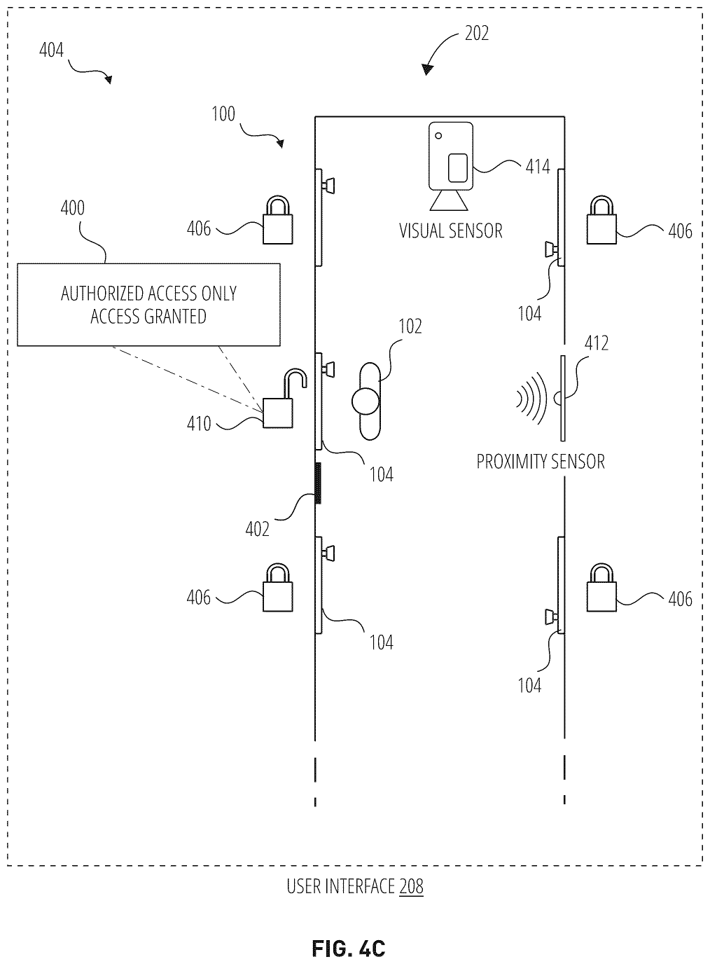

In some embodiments, the proximity translator 310 interfaces or controls one or more proximity sensors 412 (see, e.g., FIG. 4A-FIG. 4C and related discussion) that detect a presence of a guest 102. In some embodiments, a proximity sensor may include an inductive proximity sensor, a capacitive proximity sensor 412, an optical proximity sensor, an ultrasonic proximity sensor, a magnetic proximity sensor, radio frequency identification (“RFID”), NFC device, or the like. The proximity sensor 412 may generate a signal responsive to the presence of a guest 102 and relay that information the hardware layer 306 of the proximity translator 310. In some embodiments, the proximity sensor 412 may detect a proximity of an item such as a guest device 214. In some embodiments, the proximity translator 310 may identify a specific guest. As discussed herein, the hardware layer 306 may relay that information to the communications layer 304, the software layer 302, or directly to the application program interface 308 for further processing by the system 200.

In some embodiments, the show cueing translator 312 effectuates or simulates special effects such as lighting or other visual or sensory effects, sound effects, haptic effects, motion effects, smell effects, wind effects, etc. As with the other translators, the show cueing translator 312 may have a software layer 302, a communications layer 304, and/or a hardware layer 306 that interface with and/or control various effects technologies. In some embodiments, a translator such as the show cueing translator 312 may simulate a guest device 214. For example, where a guest device 214 is a smart phone, the show cueing translator 312 may simulate the user interface and interactions of the smart phone as it interacts with the interactive environment 100. The simulated guest device 214 may be displayed in the user interface 208. In another example, the show cueing translator 312 may cause the guest device 214 (real or virtual) to display certain outputs (e.g., a user interface element, lights, haptics, etc.) In this way, a designer 212 can more accurately experience what a guest 102 may experience in the interactive environment 100. In some embodiments, the show cueing translator 312 may operate in concert with the proximity translator 310 and may display different effects depending on which guest 102 is present in a particular part of the interactive environment 100.

In some embodiments, the visual analytics translator 314 effectuates or simulates visual information from the interactive environment 100. As with the other translators, the show cueing translator 312 may have a software layer 302, a communications layer 304, and/or a hardware layer 306 that interface with and/or control various visual analytics technologies. For example, the hardware layer 306 may include or be in communication with one or more visual sensors 414 (see, e.g., FIG. 4A-FIG. 4C and related discussion). The visual sensor 414 may be cameras (either still or video) that capture and relay visual information to other components of the system 200.

In some embodiments, the messaging translator 316. As with the other translators, the show cueing translator 312 may have a software layer 302, a communications layer 304, and/or a hardware layer 306 that interface with and/or control various messaging technologies. For example, the hardware layer 306 of the messaging translator 316 may include or be in communication with one or more displays 402 to display or receive messages from a guest 102 (see, e.g., FIG. 4A-FIG. 4C and related discussion). In some embodiments, the interactive environment 100 may include an interactive artificial intelligence component. The AI component may interact with a guest 102 via the messaging translator 316 and one or more displays 402, etc. In some embodiments, the messaging translator 316 may operate in concert with the proximity translator 310 and may display different messages 400 depending on which guest 102 is present in a particular part of the interactive environment 100.

In some embodiments, the entertainment subsystem 216 includes various custom translators 318 to handle specific actions or simulations, as desired. For example, a custom translator 318 may be used to implement a distributed game engine, a three-dimensional rendering engine, or the like.

In some embodiments, the entertainment subsystem 216 includes a design and prototype translator 320. The design and prototype translator 320 interfaces with components of a prototype version of an interactive system 100, or with prototype components of an interactive system 100 (e.g., a functioning production system 100 with new, experimental, or prototype components, features, or actions.

In some embodiments, the entertainment subsystem 216 includes a show control translator 322. A show control translator can interface with and simulate or control functions of a show controller. For example, a show controller may implement or control one or more of the following functions such as theatrical functions: lighting, sound, haptic, smell, or visual effects, automation, projection, animatronic or robotic effects, or the like. The show control translator 322 can (in the case of a simulated interactive environment 100) simulate these functions of a show controller. In the case of an actual interactive environment 100, the show control translator 322 can cause the show controller to implement, actuate, or deactivate these features.

The modular structure of the entertainment subsystem 216 has and advantage of enabling designer teams to rapidly deploy and scale systems 200 suitable for any number of interactive environments 100. If a certain interactive environment 100 calls for a new type of translator, that translator can be added to the entertainment subsystem 216 in any level of detail (e.g., at the software, communications, and/or physical level). Thus, the system 200 can be used to rapidly design, build, and operate a wide variety of interactive environments 100.

Turning to FIG. 4A-FIG. 4C, an example two-dimensional (“2D”) representation of an interactive environment 100 is shown in the context of a user interface 208 of the system 200. The interactive environment 100 may be simulated, designed, or executed such as with the system 200 using the user interface 208 via a computing device 204. As shown for example in FIG. 4A, the 2D representation of the interactive environment 100 may be part of a simulation environment 202. The simulation environment 202 may display a virtual or physical layout of a planned or actual interactive environment 100. In the example shown, the simulation environment 202 includes a representation of a hallway including one or more icons representing virtual object 404 such as doors 104, a proximity sensor 412, a simulated guest 102, a visual sensor 414, etc. Status of the virtual objects 404 such as the doors 104 may be displayed by nearby icons 406, such as a padlock icon showing the status of the door 104 as open, closed, locked, or unlocked, etc. As discussed with respect to the translators, any of the icons or other items displayed in the user interface 208 may represent virtual stubs (e.g., a software layer 302) of a physical item, a communications stub (e.g., a software layer 302 and a communications layer 304), a physical stub (e.g., a software layer 302, a communications layer 304, and/or a hardware layer 306), or an integrated, actual door system including the physical hardware and/or actuators related to the door 104.

As shown for example in FIG. 4A, a guest 102 (simulated or real) approaches a door 104. The presence of the guest 102 may be detected by the proximity sensor 412 in communication with the proximity translator 310. Additionally, or alternately, the presence of the guest 102 may be detected by the visual sensor 414 in communication with the visual analytics translator 314.

In response to the detection of the presence of the guest 102, the system 200 may display a message 400. In one example, where the interactive environment 100 involves being on a ship, the message 400 may say “AUTHORIZED ACCESS ONLY. PRESENT CREDENTIALS”. The message 400 may be relayed via a messaging translator 316 and shown on a display 402 near the guest 102 or the door 104. As shown for example in FIG. 4B, the guest 102 may not have the proper credentials (e.g., may not have completed a portion of the interactive environment 100). The system 200 may respond via the messaging translator 316 with a new message to be displayed on the display 402, such as “AUTHORIZED ACCESS ONLY. ACCESS DENIED.” An icon 408 in the user interface 208 may change color and/or shape to indicate that access is denied to the guest 102. For example, the interactive environment 100 may be such that a guest 102 needs to complete a side game, quest, or mini-game within the larger interactive environment 100 to gain the proper credentials to open the door 104.

In another example shown in FIG. 4C, the guest 102 may be granted access, such as by presenting the proper credential (e.g., presenting a guest device 214 to the proximity sensor 412), by detection of the presence of the guest 102 by the proximity sensor 412 or the visual sensor 414, etc. The system 200 may generate a message 400 such as “AUTHORIZED ACCESS ONLY. ACCESS GRANTED”. An icon 410 in the user interface 208 may change color and/or shape to indicate that access is granted to the guest 102.

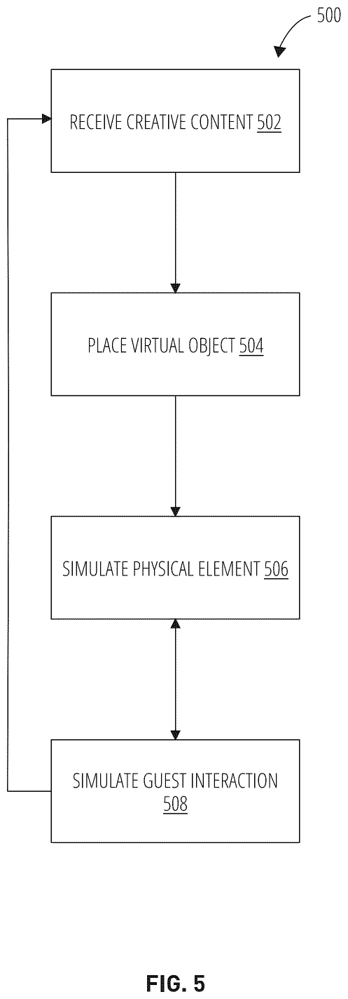

FIG. 5 illustrates an example of a method 500 for simulating an interactive environment 100 with the system 200. Although the example method 500 depicts a particular sequence of operations, the sequence may be altered without departing from the scope of the present disclosure. For example, some of the operations depicted may be performed in parallel or in a different sequence that does not materially affect the function of the routine. In other examples, different components of an example device or system that implements the routine may perform functions at substantially the same time or in a specific sequence.

According to some examples, the method 500 includes receiving creative content at operation 502. For example, a designer 212 such as a storyteller or creative team may generate a creative vision for the interactive environment 100. The creative vision may be inserted into the system 200 as a digital representation of the interactive environment 100. The interactive environment 100 may include a story line, characters, settings, and/or a time frame (e.g., historical, futuristic, present day, etc.). The creative content may include a 2D representation of the world of the interactive environment 100, which may be drawn or imported such as via the user interface 208 of the system 200.

According to some examples, the method 500 includes placing or generating a virtual object into the simulation environment 202 at operation 504. The virtual object may be a virtual representation of a physical element such as an actuator, sensor, or the like. Continuing the example of FIG. 4A and FIG. 4B, a designer 212 may place one or more virtual objects, such as a door 104, a display 402, a visual sensor 414, a proximity sensor 412, a guest 102, etc. into the simulation environment 202. Any of the virtual objects may include an associated software layer 302, communications layer 304, and/or hardware layer 306 of the related translator for a particular type of object. For example, the visual sensor 414 representation may include a software layer 302 and/or communications layer 304 that enable the visual sensor 414 to interface with the visual analytics translator 314. The virtual objects may be pre-configured with certain attributes or properties. For example, the visual sensor 414 may have a property indicating the focal length of the lens, color depth, data interface, etc. The simulation environment 202 may include templates for many types of virtual objects such as different visual sensors 414 like infrared cameras, pan-tilt-zoom cameras, guest 102 archetypes, or the like.

According to some examples, the method 500 includes simulating a physical element at operation 506. For example, the system 200 may operate or execute the simulation environment 202 with the virtual objects placed in the operation 504. In the operation 506, the system 200 may generate a physical signal configured to operate a physical actuator corresponding to a virtual actuator placed in the operation 504. As discussed, the translator for the various objects may be used to interact with, control, or receive feedback from the objects. Any of the virtual objects may be simulated at any level of detail (e.g., at the software layer 302, the communications layer 304, and/or the hardware layer 306). For example, where the actual physical hardware is unknown or unavailable, the virtual objects may be simulated as a stub using the appropriate translator. As the interactive environment 100 becomes more defined, generally, the virtual objects will have the hardware layers 306 activated or added to increase the fidelity of the simulation environment 202. In some embodiments, the operation 506 may be used to simulate or try out a software layer 302 such as a new algorithm, etc. Following a successful simulation, the software layer 302 may be promoted to a production or live environment. In some embodiments, the operation 506 includes generating physical signals (e.g., via the hardware layer 306) configured to operate a physical actuator corresponding to the virtual actuator.

According to some examples, the method 500 includes simulating guest interaction at operation 508. For example, a virtual guest 102 may be placed in the simulation environment 202. The guest 102 may be able to autonomously (or under the direction of a designer 212) interact with the simulation environment 202. In some embodiments, multiple virtual guests 102 may be placed in the simulation environment 202 such as to simulate crowding, queuing, and other guest behaviors. For example, the system 200 may run the simulation environment 202 and generate a report of guest behaviors (e.g., 30% of guests turned left at a hallway and 70% turned right). In some embodiments, the guests 102 may have different properties or archetypes. For example, the guest 102 may be a family-type guest, a child-type guest, or a power player type guest. In some embodiments, the guest 102 may have unusual properties (e.g., the guest 102 may have multiple guest devices 214) and the effects of those unusual properties can be simulated before an actual guest 102 uses the interactive environment 100. In some examples virtual guest interactions are randomly generated. In some examples, virtual guest interactions are based on historical guest inputs from guests interacting with the physical interactive environment.

In either of both of the operation 506 and/or operation 508 a designer 212 may manipulate simulated time. For example, the designer 212 may move a virtual time marker forward or backward, e.g., to replay or retest the simulated objects or guests under various circumstances. In some embodiments, the system 200 may be used to automatically run simulations (such as a Monte Carlo simulation) of the interactive environment 100 to determine likely outcomes for various guests 102. Such functionality can be highly advantageous over prior methods, given the possible thousands or millions of branching realities a guest 102 may experience in an interactive environment 100. Manually simulating all these millions of possibilities is simply not possible without the system 200.

In another use case of the system 200 as a virtual twin of the interactive environment 100, a designer 212 may be able to patch broken game play for a guest 102 by changing the story line dynamically for one or more guests 102. For example, a guest 102 may have run their particular branching story into a dead end, or families may have become splintered into separate, non-overlapping story lines. Through the operation 506 and/or operation 508, the system 200 can fix or patch issues such as these, thereby re-inserting a guest 102 into the narrative or re-uniting families into the same interactive environment.

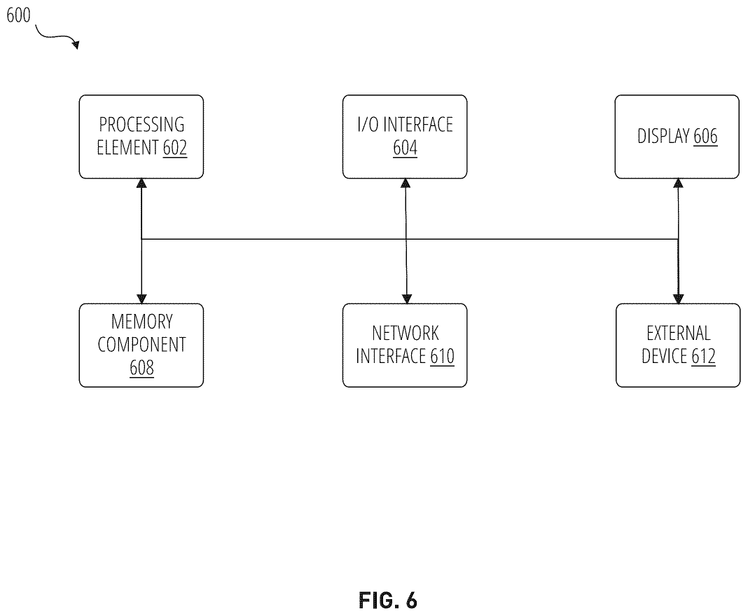

FIG. 6 is a simplified block diagram of components of a computing system 600 of the interactive environment 100 or system 200, such as the computing device 204, the guest device 214, the database 210, or one or more sensors or actuators. For example, the processing element 602 and the memory component 608 may be located at one or in several computing systems 600. This disclosure contemplates any suitable number of such computing systems 600. For example, the computing device 204 may be a desktop computing system, a mainframe, a blade, a mesh of computing systems 600, a laptop or notebook computing system 600, a tablet computing system 600, an embedded computing system 600, a system-on-chip, a single-board computing system 600, or a combination of two or more of these. Where appropriate, a computing system 600 may include one or more computing systems 600; be unitary or distributed; span multiple locations; span multiple machines; span multiple data centers; or reside in a cloud, which may include one or more cloud components in one or more networks. A computing system 600 may include one or more processing elements 602, an input/output I/O interface 604, one or more external devices 612, one or more memory components 608, and a network interface 610. Each of the various components may be in communication with one another through one or more buses or communication networks, such as wired or wireless networks, e.g., the network 206. The components in FIG. 6 are exemplary only. In various examples, the computing system 600 may include additional components and/or functionality not shown in FIG. 6.

The processing element 602 may be any type of electronic device capable of processing, receiving, and/or transmitting instructions. For example, the processing element 602 may be a central processing unit, microprocessor, processor, or microcontroller. Additionally, it should be noted that some components of the computing system 600 may be controlled by a first processing element 602 and other components may be controlled by a second processing element 602, where the first and second processing elements may or may not be in communication with each other.

The I/O interface 604 allows a designer to enter data in to computing system 600, as well as provides an input/output for the computing system 600 to communicate with other devices or services. The I/O interface 604 can include one or more input buttons, touch pads, touch screens, and so on.

The external device 612 are one or more devices that can be used to provide various inputs to the computing systems 600, e.g., mouse, microphone, keyboard, trackpad, sensing element (e.g., a thermistor, humidity sensor, light detector, etc. The external devices 612 may be local or remote and may vary as desired. In some examples, the external devices 612 may also include one or more additional sensors.

The memory components 608 are used by the computing system 600 to store instructions for the processing element 602 such as the database 210, elements of the software layer 302 and/or communications layers 304, messages 400, guest 102 data, designer preferences, alerts, etc. The memory components 608 may be, for example, magneto-optical storage, read-only memory, random access memory, erasable programmable memory, flash memory, or a combination of one or more types of memory components.

The network interface 610 provides communication to and from the computing system 600 to other devices. The network interface 610 includes one or more communication protocols, such as, but not limited to Wi-Fi, Ethernet, Bluetooth, etc. The network interface 610 may also include one or more hardwired components, such as a Universal Serial Bus (USB) cable, or the like. The configuration of the network interface 610 depends on the types of communication desired and may be modified to communicate via Wi-Fi, Bluetooth, etc.

The display 606 provides a visual output for the computing system 600 and may be varied as needed based on the device. The display 606 may be configured to provide visual feedback to the designer 212 or guest 102 and may include a liquid crystal display screen, light emitting diode screen, plasma screen, or the like. In some examples, the display 606 may be configured to act as an input element for the designer 212 or guest 102 through touch feedback or the like.

Any description of a particular component being part of a particular embodiment, is meant as illustrative only and should not be interpreted as being required to be used with a particular embodiment or requiring other elements as shown in the depicted embodiment.

All relative, directional, and ordinal references (including top, bottom, side, front, rear, first, second, third, and so forth) are given by way of example to aid the reader's understanding of the examples described herein. They should not be read to be requirements or limitations, particularly as to the position, orientation, or use unless specifically set forth in the claims. Connection references (e.g., attached, coupled, connected, joined, and the like) are to be construed broadly and may include intermediate members between a connection of elements and relative movement between elements. As such, connection references do not necessarily infer that two elements are directly connected and in fixed relation to each other, unless specifically set forth in the claims.

The present disclosure teaches by way of example and not by limitation. Therefore, the matter contained in the above description or shown in the accompanying drawings should be interpreted as illustrative and not in a limiting sense. The following claims are intended to cover all generic and specific features described herein, as well as all statements of the scope of the present method and system, which, as a matter of language, might be said to fall there between.

What is claimed is:

1. A system for simulating an interactive physical environment comprising:
a physical actuator positioned within the interactive physical environment; and
a translator configured to:
generate a digital representation of the interactive physical environment including a virtual actuator in a digital location, wherein the virtual actuator is representative of the physical actuator;
generate a virtual command for an action of the virtual actuator;
translate the virtual command into a physical signal for the physical actuator; and
output the physical signal to the physical actuator.

2. The system of claim 1, wherein the translator is further configured to:
receive a guest interaction input interacting with at least one of the virtual actuator or the physical actuator; and
activate the at least one of the virtual actuator or the physical actuator based on the guest interaction input.

3. The system of claim 2, wherein the guest interaction input comprises a guest interaction within the interactive physical environment or a simulated guest interaction within the digital representation.

4. The system of claim 1, wherein the translator comprises:
a software layer;
a communications layer in communication with the software layer; and
a hardware layer in communication with the software layer, the communications layer, or both.

5. The system of claim 4, wherein simulating the virtual actuator comprises executing by the software layer a simulation that emulates a characteristic of the physical actuator.

6. The system of claim 4, wherein simulating the virtual actuator comprises causing the processing element to execute the communications layer to emulate a data exchange with the physical actuator.

7. The system of claim 4, wherein simulating the virtual actuator comprises causing the processing element to execute the hardware layer to create a physical output compatible with the physical actuator.

8. The system of claim 4, wherein the translator comprises at least one of a proximity translator, a show cueing translator, a visual analytics translator, or a messaging translator.

9. The system of claim 1, wherein simulating the guest interaction comprises simulating a guest device or a guest archetype.

10. The system of claim 1, wherein simulating the guest interaction comprises autonomously simulating a plurality of guests interacting with the interactive environment.

11. The system of claim 4, wherein the processing element is configured to:
display a graphical user interface including a two-dimensional representation of the interactive environment;
receive, via the graphical user interface, a user input related to the interactive environment,
translate the user input into the physical signal,
transmit the physical signal to the physical actuator;
in response to the transmission of the physical signal, receive a confirmation signal from the physical actuator, and
update the graphical user interface based on the confirmation.

12. The system of claim 4, wherein the system further comprises a digital twin of the interactive environment.

13. A method of simulating an interactive physical environment comprising:
positioning a physical actuator within the interactive physical environment;
generating, via a processing element, a digital representation of the interactive physical environment including a virtual actuator in a digital location, wherein the virtual actuator is representative of the physical actuator;
generating, via the processing element, a virtual command for an action of the virtual actuator;
translating, via the processing element, the virtual command into a physical signal for the physical actuator; and
outputting, via the processing element, the physical signal to the physical actuator.

14. The method of claim 13, further comprising executing, via the processing element, a translator including:
a software layer;
a communications layer in communication with the software layer; and
a hardware layer in communication with the software layer, the communications layer or both, wherein the translator is configured to simulate the virtual actuator.

15. The method of claim 14, wherein simulating the virtual actuator comprises causing the processing element to perform at least one of:
executing the software layer to emulate a characteristic of the physical actuator;
executing the communications layer to emulate a data exchange with the physical actuator; or
executing the hardware layer to create a physical output compatible with the physical actuator.

16. The method of claim 13, wherein simulating the guest interaction comprises simulating a guest device or a guest archetype.

17. The method of claim 13, wherein the processing element is configured to:
display a graphical user interface including a two-dimensional representation of the interactive environment;
receive, via the graphical user interface, a user input related to the interactive environment,
translate the user input into the physical signal,
transmit the physical signal to the physical actuator;
in response to the transmission of the physical signal, receive a confirmation signal from the physical actuator, and
update the graphical user interface based on the confirmation.

18. A method for simulating guest interactions within a physical interactive environment comprising:
generating a digital twin of the physical interactive environment, the digital twin comprising a plurality of virtual actuators corresponding to physical actuators positioned within the physical interactive environment, wherein the plurality of virtual actuators are configured to vary environmental characteristics based on a guest input and creative constraints;
providing a plurality of guest inputs to the plurality of virtual actuators, wherein the plurality of guest inputs are different from one another; and
outputting data corresponding to the varied environmental characteristics and creative constraints based on the provided plurality of guest inputs.

19. The method of claim 18, wherein the plurality of guest inputs is randomly generated.

20. The method of claim 18 wherein the plurality of guest inputs is based on historical guest inputs from guests interacting with the physical interactive environment.
